(19) United States
(12) Patent Application Publication
(10) Pub. No.: US 2026/0140139 A1
(43) Pub. Date: May 21, 2026

(54) TEST DEVICE, TEST BOARD, AND TEST METHOD USING THE SAME

(71) Applicant: Samsung Electronics Co., Ltd., Suwon-si (KR)

(72) Inventors: Geukchan KIM, Suwon-si (KR); Kiwoong YOO, Suwon-si (KR); Donghan YOON, Suwon-si (KR)

(73) Assignee: Samsung Electronics Co., Ltd., Suwon-si (KR)

(21) Appl. No.: 19/371,621

(22) Filed: Oct. 28, 2025

(30) Foreign Application Priority Data
Nov. 21, 2024 (KR) 10-2024-0167235

(51) Int. Cl. G01R 1/04; G01R 31/28

(52) U.S. Cl. CPC G01R 1/0466; G01R 31/2834

(57) ABSTRACT

Disclosed is a test device including a mother board and a plurality of daughter boards. The plurality of daughter boards are selectively coupled to the mother board and configured to provide a plurality of test signals from a device under test to the mother board. Each of the plurality of daughter boards includes a substrate, a socket, and a connector. The socket is mounted on the substrate and configured to output a corresponding test signal among the plurality of test signals through a first socket pin. The connector is mounted on the substrate and configured to output the corresponding test signal from the socket to the mother board through a first connector pin. Relative positions between the first connector pins and the first socket pins on the plurality of daughter boards are the same.

### CROSS-REFERENCE TO RELATED APPLICATIONS

This application claims priority under 35 U.S.C. § 119 to Korean Patent Application No. 10-2024-0167235 filed on Nov. 21, 2024, in the Korean Intellectual Property Office, the disclosure of which is incorporated by reference herein in its entirety.

### BACKGROUND

Some example embodiments described herein relate to a semiconductor device, and more particularly, relate to a test device, a test board, and/or a test method using the test device and the test board.

In a process of developing and testing a semiconductor device, the semiconductor device to be tested is mounted on a test board, and an external tester applies signals to the test board, monitors signals output from the semiconductor device, and observes and determines one or more of skew, jitter, and the like that are present in the signals, thereby determining the performance or reliability of the semiconductor device. In some cases, underperforming product may be either scrapped or downgraded.

However, due to the structure and characteristics of the test board itself, the consistency of a test condition may not be guaranteed so that the test result of the semiconductor device may be adversely affected, and due to the manufacturing time and/or cost of the test board, a process of maintaining or repairing the semiconductor device in response to the test result may also be affected.

### SUMMARY

Some example embodiments may provide a test device and/or a test board for improving signal integrity shown in a test result. Alternatively or additionally, some example embodiments may provide a test device and/or a test board for reducing the manufacturing time and/or cost of the test board.

Alternatively or additionally, some example embodiments may provide a test method using the test device and the test board.

According to some example embodiments, a test device includes a mother board and a plurality of daughter boards. The plurality of daughter boards are selectively coupled to the mother board and are configured to provide a plurality of test signals from a device under test to the mother board. Each of the plurality of daughter boards includes a substrate, a socket, and a connector. The socket is mounted on the substrate and is configured to output a corresponding test signal among the plurality of test signals through a first socket pin. The connector is mounted on the substrate and is configured to output the corresponding test signal from the socket to the mother board through a first connector pin. Relative positions between the first connector pins and the first socket pins on the plurality of daughter boards are same.

Alternatively or additionally according to some example embodiments, a test board includes a substrate, a socket, and a connector. The socket is mounted on the substrate and is configured to output a first test signal among a plurality of test signals from a device under test through a first socket pin. The connector is mounted on the substrate and is configured to output the first test signal from the socket to a mother board through a first connector pin. The test board is one of a plurality of daughter boards that are selectively coupled to the mother board and that are configured to provide the plurality of test signals to the mother board. A position of the socket is determined such that the first socket pin is located a first distance away from the first connector pin in a first direction.

Alternatively or additionally, in a test method, a device under test is attached to a first daughter board such that a first output terminal of the device under test is located at a first point of the first daughter board. The first daughter board is attached to a mother board such that a connector of the first daughter board is located at a reference point of the mother board. A first test signal output from the first output terminal is tested. The device under test is attached to a second daughter board such that a second output terminal of the device under test is located at a second point of the second daughter board. The second daughter board is attached to the mother board such that a connector of the second daughter board is located at the reference point of the mother board. A second test signal output from the second output terminal is tested. At least one of a direction and a distance from a point at which the connector of the first daughter board is located to the first point are the same as a respective one of a direction and a distance from a point at which the connector of the second daughter board is located to the second point.

Alternatively or additionally according to some example embodiments, a test system comprises an automated test equipment (ATE) configured to test device under tests (DUTs) by receiving a plurality of first test signals, a mother board configured to send the first signals to the ATE, and a plurality of daughter boards configured to be mounted on the mother board and configured to communicate with the mother board, each of the plurality of daughter boards configured to receive a plurality of second test signals from a DUT mounted on to the daughter board, wherein the second test signals are based on the first test signals,. each of the plurality of daughter boards includes a connector configured to send at least one of the plurality of second test signals to the mother board through a first connector pin, and a socket configured to send at least one of the second test signals through a first socket pin. Relative positions between the first connector pins and the first socket pins on the plurality of daughter boards are same.

In some example embodiments, the ATE is configured to scrap at least one DUT based on the second test signals.

In some example embodiments, the ATE is configured to downgrade at least one DUT based on the second test signals.

### BRIEF DESCRIPTION OF THE FIGURES

The above and other objects and features of inventive concepts will become apparent by describing in detail some example embodiments thereof with reference to the accompanying drawings.

FIG. 1 is a view illustrating a test system including a test device according to some example embodiments.

FIGS. 2A, 2B, and 2C are views illustrating embodiments of a device under test of FIG. 1.

FIG. 3 is a view for explaining output terminals of a device under test of FIG. 2A.

FIG. 4 is a view for explaining an embodiment of the position of a socket to which the device under test of FIG. 2A is attached on each daughter board.

FIGS. 5 and 6 are views for explaining the positions of sockets of FIG. 4.

FIG. 7 is a view for explaining output terminals of a device under test of FIG. 2B.

FIG. 8 is a view for explaining an embodiment of the position of a socket to which the device under test of FIG. 2B is attached on each daughter board.

FIG. 9 is a view for explaining output terminals of a device under test of FIG. 2C.

FIG. 10 is a view for explaining an embodiment of the position of a socket to which the device under test of FIG. 2C is attached on each daughter board.

FIG. 11 is a flowchart illustrating a test method according to some example embodiments.

### DETAILED DESCRIPTION

Hereinafter, some example embodiments will be described clearly and in detail to such an extent that those skilled in the art easily implement the present disclosure.

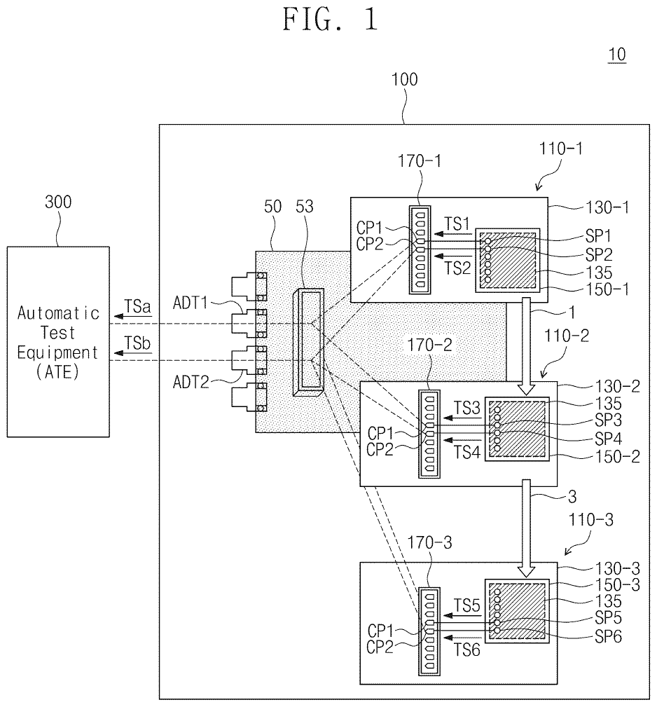

FIG. 1 is a view illustrating a test system including a test device according to some example embodiments.

Referring to FIG. 1, the test system 10 may include the test device 100 and automatic test equipment (ATE) 300 that controls the test device 100. The test device 100 may include a mother board 50 and a plurality of daughter boards 110-1, 110-2, and 110-3 and may be referred to as a “test module”, a “test assembly”, or an “integrated test board”.

Each of the plurality of daughter boards 110-1, 110-2, and 110-3 may have the same or the kind of device under test 135 (or, DUT) mounted thereon, e.g., at the same time or at different times. The plurality of daughter boards 110-1, 110-2, and 110-3 may be or may include test boards that are sequentially coupled to the mother board 50 or replaced (e.g., 1 and 3) and that transmit different test signals output from the device under test 135 to the ATE 300 through the mother board 50. For example, the daughter board 110-1 may transmit a first test signal output from a first output terminal of the device under test 135 to the ATE 300 through the mother board 50, the daughter board 110-2 may transmit a second test signal output from a second output terminal of the device under test 135 to the ATE 300 through the mother board 50, and the daughter board 110-3 may transmit a third test signal output from a third output terminal of the device under test 135 to the ATE 300 through the mother board 50. For example, as the plurality of daughter boards 110-1, 110-2, and 110-3 are sequentially coupled to the mother board 50 and/or are replaced, the device under test 135 may also be sequentially coupled to the different daughter boards from one daughter board to another daughter board.

The ATE 300 may control the mother board 50 and the plurality of daughter boards 110-1, 110-2, and 110-3 to send and receive and monitor the different test signals sent to or output from the output terminals of the device under test 135. For example, the ATE 300 may include a power supply circuit for supplying powers for operations of the boards 50, 110-1, 110-2, and 110-3 to the mother board 50 and the plurality of daughter boards 110-1, 110-2, and 110-3. The ATE 300 may transmit one or more of command signals, address signals, and data signals to the device under test 135 through the mother board 50 and the plurality of daughter boards 110-1, 110-2, and 110-3 and may monitor data signals output from the device under test 135 through the plurality of daughter boards 110-1, 110-2, and 110-3 and the mother board 50.

Each of the plurality of daughter boards 110-1, 110-2, and 110-3 may include a substrate, a socket, and a connector. The socket may be mounted on the substrate and may output a corresponding test signal output from a corresponding output terminal of the device under test 135 through a socket pin. The connector may be mounted on the substrate and may output the corresponding test signal from the socket to the mother board 50 through a connector pin.

For example, the daughter board 110-1 may include a substrate 130-1, and a socket 150-1 and a connector 170-1 that are mounted on the substrate 130-1. The socket 150-1 may output corresponding test signals (e.g., TS1 and TS2) through socket pins SP1 and SP2, and the connector 170-1 may output the corresponding test signals from the socket 150-1 to the mother board 50 through connector pins (e.g., CP1 and CP2). For example, the daughter board 110-2 may include a substrate 130-2, and a socket 150-2 and a connector 170-2 that are mounted on the substrate 130-2. The socket 150-2 may output corresponding test signals (e.g., TS3 and TS4) through socket pins SP3 and SP4, and the connector 170-2 may output the corresponding test signals from the socket 150-2 to the mother board 50 through connector pins (e.g., CP1 and CP2). For example, the daughter board 110-3 may include a substrate 130-3, and a socket 150-3 and a connector 170-3 that are mounted on the substrate 130-3. The socket 150-3 may output corresponding test signals (e.g., TS5 and TS6) through socket pins SP5 and SP6, and the connector 170-3 may output the corresponding test signals from the socket 150-3 to the mother board 50 through connector pins (e.g., CP1 and CP2).

The relative positions, e.g., the pitch, between the connector pins and the socket pins on the plurality of daughter boards 110-1, 110-2, and 110-3 may be the same. For example, the plurality of daughter boards 110-1, 110-2, and 110-3 may be manufactured such that the distances between the connector pins and the socket pins are substantially the same; e.g., the connector pins and the socket pins are arranged at a constant pitch. Since the socket pins are electrically connected with the connector pins on the plurality of daughter boards 110-1, 110-2, and 110-3, the lengths of paths along which the test signals output from the output terminals of the device under test 135 reach the connector pins through the socket pins may be the same. For example, the directions and/or distances from the connector pins to the socket pines on the plurality of daughter boards 110-1, 110-2, and 110-3 may be the same. The connector pins and the socket pins may mean one or more pins on the plurality of daughter boards 110-1, 110-2, and 110-3 that are involved in the output of the corresponding test signals. For example, on the plurality of daughter boards 110-1, 110-2, and 110-3, the socket pins may be electrically coupled with the corresponding output terminals of the device under test 135 and may output the corresponding test signals, and the connector pins may receive the test signals output from the socket pins and may transmit the test signals to a connector 53 of the mother board 50.

In some example embodiments, the device under test 135 may be coupled to the sockets 150-1, 150-2, and 150-3 of the plurality of daughter boards 110-1, 110-2, and 110-3 in the same coupling direction, and the sockets 150-1, 150-2, and 150-3 may be mounted in a parallel state at different positions on the plurality of daughter boards 110-1, 110-2, and 110-3. Accordingly, the relative positions between the connector pins and the socket pins on the plurality of daughter boards 110-1, 110-2, and 110-3 may be the same. In some example embodiments, the device under test 135 may be coupled to the sockets 150-1, 150-2, and 150-3 of the plurality of daughter boards 110-1, 110-2, and 110-3 in different coupling directions, and the sockets 150-1, 150-2, and 150-3 may be mounted in a parallel state or a rotated state at different positions on the plurality of daughter boards 110-1, 110-2, and 110-3. Accordingly, the relative positions between the connector pins and the socket pins on the plurality of daughter boards 110-1, 110-2, and 110-3 may be the same. For example, the coupling direction of the device under test 135 and the mounting positions of the sockets 150-1, 150-2, and 150-3 may be relatively determined based on the positions and/or the shapes of the connectors 170-1, 170-2, and 170-3 of the plurality of daughter boards 110-1, 110-2, and 110-3. However, the spirit and scope of example embodiments are not limited thereto.

In some example embodiments, the device under test 135 may be or may include (or be included in) a universal flash storage (UFS) device, and the test signals output from the socket pins SP1 and SP2 of the daughter board 110-1, the socket pins SP3 and SP4 of the daughter board 110-2, or the socket pins SP5 and SP6 of the daughter board 110-3 may be differential signals depending on a full-duplex low-voltage differential signaling (LVDS) serial interface and/or signals received through one lane of a UFS interface. In this case, the relative position between the connector pin CP1 and the socket pin SP1 of the daughter board 110-1 may be the same as the relative position between the connector pin CP1 and the socket pin SP3 of the daughter board 110-2, and may also be the same as the relative position between the connector pin CP1 and the socket pin SP5 of the daughter board 110-3. The relative position between the connector pin CP2 and the socket pin SP2 of the daughter board 110-1 may be the same as the relative position between the connector pin CP2 and the socket pin SP4 of the daughter board 110-2, and may also be the same as the relative position between the connector pin CP2 and the socket pin SP6 of the daughter board 110-3. Accordingly, in the process of transmitting the different test signals of the device under test 135 to the ATE 300 through the mother board 50, the plurality of daughter boards 110-1, 110-2, and 110-3 may transmit the different test signals to the mother board 50 under substantially the same condition (for example, the relative positions between the connectors and the socket pins of the daughter boards (or, the output terminals of the device under test connected with the socket pins) are the same). For example, the test signals TS1 and TS2 may be transmitted to the ATE 300 as test signals TSa and TSb through the connector 170-1 of the daughter board 110-1 and the connector 53 and adaptors ADT1 and ADT2 of the mother board 50, the test signals TS3 and TS4 may be transmitted to the ATE 300 as test signals TSa and TSb through the connector 170-2 of the daughter board 110-2 and the connector 53 and the adaptors ADT1 and ADT2 of the mother board 50, and the test signals TS5 and TS6 may be transmitted to the ATE 300 as test signals TSa and TSb through the connector 170-3 of the daughter board 110-3 and the connector 53 and the adaptors ADT1 and ADT2 of the mother board 50. The test signals TS1 and TS2, the test signals TS3 and TS4, and the test signals TS5 and TS6 may be transmitted from the respective daughter boards to the ATE 300 through paths having the same direction and length and accordingly may be transmitted under the same condition. For example, under the same condition, the paths along which the test signals TS1 and TS2, the test signals TS3 and TS4, and the test signals TS5 and TS6 are output may have substantially the same channel loss characteristic value and may have the same length. Because the relative positions are the same, the test signals will see the same (or substantially the same) current-resistance (IR) drop.

In FIG. 1, three daughter boards 110-1, 110-2, and 110-3 are illustrated, and the configuration in which the test signals are output through two socket pins of each of the daughter boards 110-1, 110-2, and 110-3 has been described. However, the number of the daughter boards and/or the number of the socket pins through which the test signals are output from each daughter board are merely illustrative.

The above-configured test device according to the some example embodiments may transmit the different test signals from the device under test to the ATE under the same condition, which may improve the signal integrity of the test signals, thereby preventing or reducing the likelihood of and/or impact from the test result of the semiconductor device from being adversely affected by the structure and characteristics of the test board itself, and/or by improving the reliability of analysis. In the test device, the daughter boards may be manufactured separately from the mother board so as to be detachable, and only the daughter boards may be newly manufactured for a new device under test. Accordingly, it may be possible to reduce the manufacturing time and/or cost of the test board while supporting various form factors.

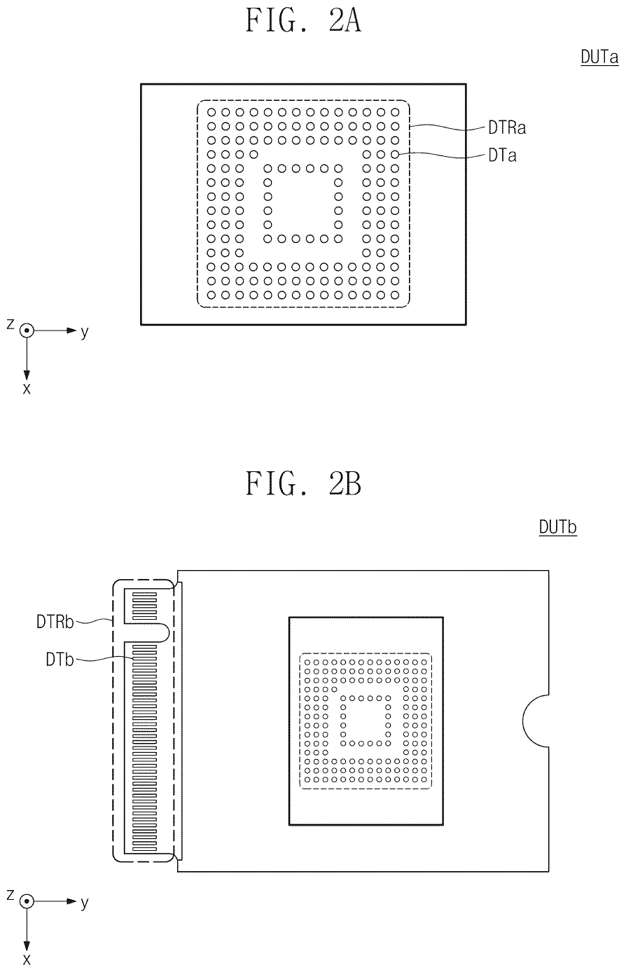

FIGS. 2A, 2B, and 2C are views illustrating embodiments of the device under test of FIG. 1.

As described above with reference to FIG. 1, the device under test 135 may be or may include a UFS device. As illustrated in FIGS. 2A, 2B, and 2C, different device under tests 135 may have different types. Directions X, Y, and Z orthogonal to one another are illustrated in FIGS. 2A, 2B, and 2C and are uniformly used in the following descriptions and drawings. The directions X and Y may be referred to as horizontal directions, and the direction Z may be referred to as a vertical direction.

Referring to FIG. 2A, a device under test DUTa may have a UFS fine ball grid array (FBGA) type. The device under test DUTa may include an output terminal area DTRa in which output terminals DTa are arranged in two dimensions.

Referring to FIG. 2B, a device under test DUTb may have a UFS M.2 type. The device under test DUTb may include an output terminal area DTRb in which output terminals DTb are arranged in one dimension (e.g., in a linear form).

Referring to FIG. 2C, a device under test DUTc may have a UFS card type. The device under test DUTc may include an output terminal area DTRc in which output terminals DTc are arranged in one dimension or in two dimensions.

As described above with reference to FIG. 1, the relative positions between the connector pins and the socket pins on the plurality of daughter boards 110-1, 110-2, and 110-3 may be the same. The socket pins may mean or may indicate one or more pins on the plurality of daughter boards 110-1, 110-2, and 110-3 that are involved in the output of the corresponding test signals, and the output terminals DTa, DTb, and DTc illustrated in FIGS. 2A, 2B, and 2C may be electrically connected with the socket pins in a test process and may output corresponding test signals under the control of an ATE (e.g., 300 of FIG. 1).

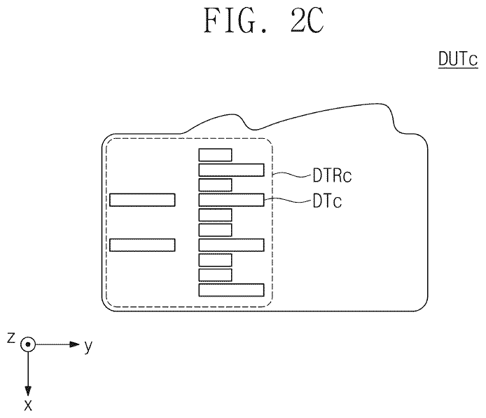

FIG. 3 is a view for explaining the output terminals of the device under test of FIG. 2A.

Devices under test DUT11, DUT12, DUT13, and DUT14 are illustrated in FIG. 3, and each of the devices under test DUT11, DUT12, DUT13, and DUT14 may correspond to the device under test DUTa described above with reference to FIG. 2A. Despite the illustration of FIG. 3, each of the devices under test DUT11 to DUT14 may be a single semiconductor device and may be separately illustrated for convenience to describe test signals output from different output terminals.

Referring to FIG. 3, output terminals DT111 and DT112 of the device under test DUT11, output terminals DT121 and DT122 of the device under test DUT12, output terminals DT131 and DT132 of the device under test DUT13, and output terminals DT141 and DT142 of the device under test DUT14 may be or correspond to target terminals TRG_DT that output different test signals. For example, the output terminals DT111, DT112, DT121, DT122, DT131, DT132, DT141, and DT142 may be data terminals that output data signals from the devices under test DUT11 to DUT14. However, the spirit and scope of example embodiments are not limited thereto.

In some example embodiments, the devices under test DUT11 to DUT14 illustrated in FIG. 3 may be mounted on different daughter boards, respectively, in the direction of coupling of the devices under test DUT11 to DUT14 in their original form, and as described above with reference to FIG. 1, the test signals output through the target terminals TRG_DT may be transmitted to an ATE (e.g., 300 of FIG. 1) under substantially the same condition.

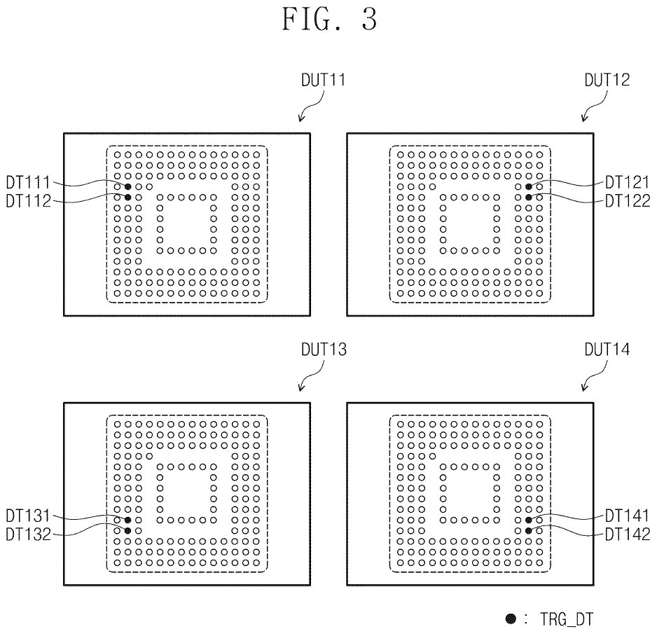

FIG. 4 is a view for explaining some example embodiments of the position of a socket to which the device under test of FIG. 2A is attached on each daughter board.

Referring to FIGS. 2A, 3, and 4, daughter boards D_BOARD11, D_BOARD12, D_BOARD13, and D_BOARD14 may have the devices under test DUT11 to DUT14 mounted thereon.

For example, the daughter board D_BOARD11 may include a socket SCKT11 for mounting the device under test DUT11 and a connector CNCT11 that is electrically connected with the socket SCKT11 and that transmits test signals output from the device under test DUT11 to a mother board. The test signals may be transmitted to the mother board through the output terminals DT111 and DT112 of the device under test DUT11, socket pins SP111 and SP112 of the socket SCKT11, and connector pins CP1 and CP2 of the connector CNCT11.

For example, the daughter board D_BOARD12 may include a socket SCKT12 for mounting the device under test DUT12 and a connector CNCT12 that is electrically connected with the socket SCKT12 and that transmits test signals output from the device under test DUT12 to the mother board. The test signals may be transmitted to the mother board through the output terminals DT121 and DT122 of the device under test DUT12, socket pins SP121 and SP122 of the socket SCKT12, and connector pins CP1 and CP2 of the connector CNCT12.

For example, the daughter board D_BOARD13 may include a socket SCKT13 for mounting the device under test DUT13 and a connector CNCT13 that is electrically connected with the socket SCKT13 and that transmits test signals output from the device under test DUT13 to the mother board. The test signals may be transmitted to the mother board through the output terminals DT131 and DT132 of the device under test DUT13, socket pins SP131 and SP132 of the socket SCKT13, and connector pins CP1 and CP2 of the connector CNCT13.

For example, the daughter board D_BOARD14 may include a socket SCKT14 for mounting the device under test DUT14 and a connector CNCT14 that is electrically connected with the socket SCKT14 and that transmits test signals output from the device under test DUT14 to the mother board. The test signals may be transmitted to the mother board through the output terminals DT141 and DT142 of the device under test DUT14, socket pins SP141 and SP142 of the socket SCKT14, and connector pins CP1 and CP2 of the connector CNCT14.

As illustrated in FIG. 4, the relative positions between the connector pins and the socket pins on the daughter boards D_BOARD11 to D_BOARD14 may be the same. For example, the relative positions between the connector pins CP1 and CP2 and the socket pins SP111 and SP112 on the daughter board D_BOARD11, the relative positions between the connector pins CP1 and CP2 and the socket pins SP121 and SP122 on the daughter board D_BOARD12, the relative positions between the connector pins CP1 and CP2 and the socket pins SP131 and SP132 on the daughter board D_BOARD13, and the relative positions between the connector pins CP1 and CP2 and the socket pins SP141 and SP142 on the daughter board D_BOARD14 may all be the same. Accordingly, there may be the same or similar IR drop as between the connector pins and the socket pins.

To this end, on the daughter boards D_BOARD11 to D_BOARD14, the sockets SCKT11 to SCKT14 are mounted at different positions in relation to the connectors CNT11 to CNT14. For example, the sockets SCKT11 to SCKT14 may be mounted in a parallel state and/or a rotated state at different positions on the daughter boards D_BOARD11 to D_BOARD14.

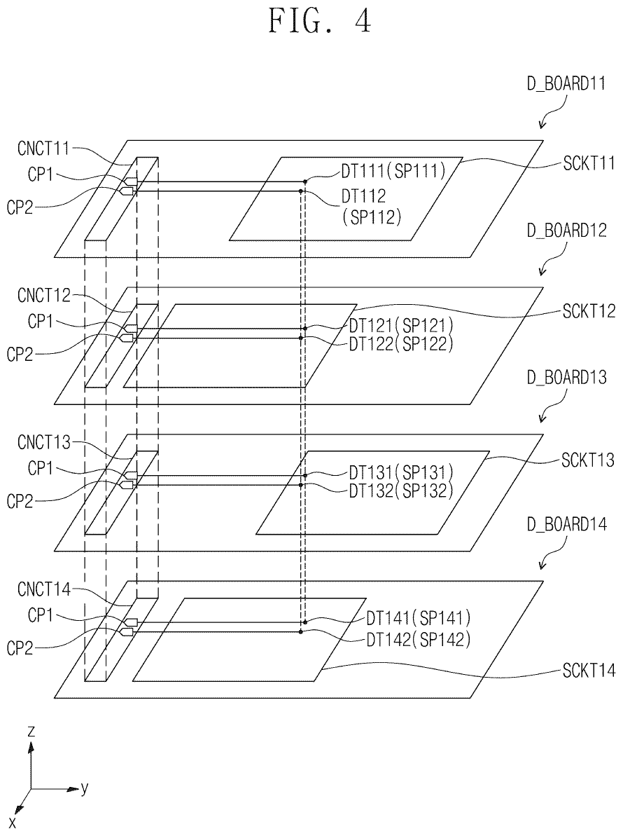

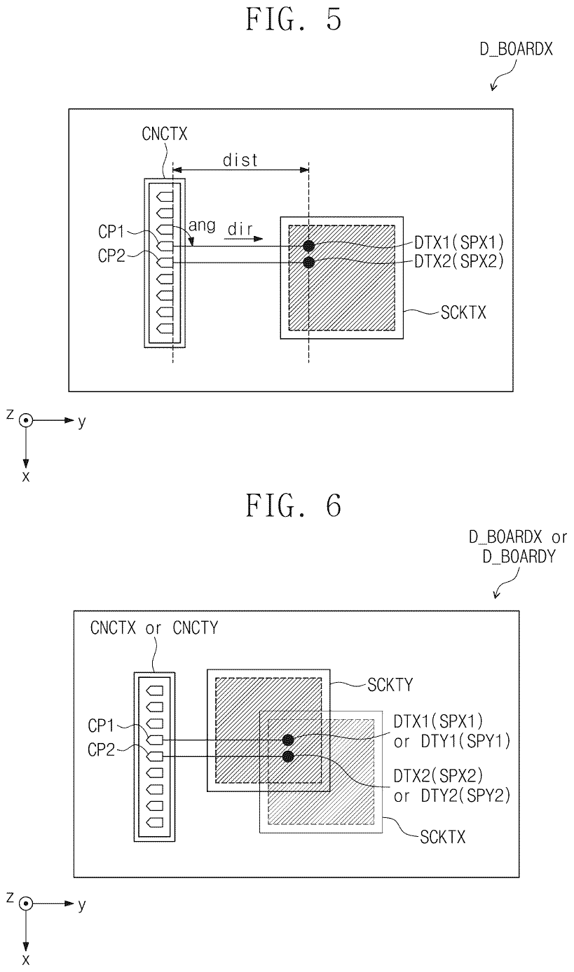

FIGS. 5 and 6 are views for explaining the positions of the sockets of FIG. 4.

Referring to FIGS. 4 and 5, a daughter board D_BOARDX may be one of the daughter boards D_BOARD11 to D_BOARD14 of FIG. 4, a connector CNCTX may be one of the connectors CNCT11 to CNCT14 of FIG. 4, and a socket SCKTX may be one of the sockets SCKT11 to SCKT14 of FIG. 4.

In some example embodiments, the position of the socket SCKTX on a substrate of the daughter board D_BOARDX may be determined such that socket pins (e.g., SPX1 and SPX2) are located at particular, e.g., dynamically determine points (or, alternatively, predetermined points) on the substrate. For example, the socket pins SPX1 and SPX2 may be located a distance dist away from connector pins CP1 and CP2 in a direction dir.

For example, the connector CNCTX may include connector pins (e.g., CP1 and CP2) involved in the output of test signals and connectors pins not involved in the output of the test signals and arranged in a line (e.g., a straight line). The socket SCKTX may also include socket pins (e.g., SPX1 and SPX2) involved in the output of the test signals and socket pins not involved in the output of the test signals and arranged in one dimension or in two dimensions.

In some example embodiments, the plurality of connector pins and the plurality of socket pins may be parallel to each other. However, the spirit and scope of the present disclosure is not limited thereto.

In some example embodiments, the direction dir may be a direction perpendicular to the lengthwise direction of the connector CNCTX (e.g., ang being 90 degrees). However, the spirit and scope of example embodiments are not limited thereto. The lengthwise direction of the connector CNCTX may mean the direction in which the plurality of connector pins are arranged.

In some example embodiments, the distance dist may be determined based on the size of a device under test and/or the size of the socket SCKTX. For example, the distance dist may be increased as the size of the device under test and/or the size of the socket SCKTX is increased.

Referring to FIGS. 4 and 6, daughter boards D_BOARDX and D_BOARDY may correspond to two of the daughter boards D_BOARD11 to D_BOARD14 of FIG. 4, connectors CNCTX and CNCTY may correspond to two of the connectors CNCT11 to CNCT14 of FIG. 4, and sockets SCKTX and SCKTY may correspond to two of the sockets SCKT11 to SCKT14 of FIG. 4.

In some example embodiments, the position of the socket SCKTX or SCKTY on a substrate of the daughter board D_BOARDX may be determined such that socket pins (e.g., SPX1 and SPX2 in the case of SCKTX or SPY1 and SPY2 in the case of SCKTY) are located at points such as dynamically determined points (or, alternatively, predetermined points) on the substrate. For example, the socket pins SPX1 and SPX2 may be located a distance (dist of FIG. 4) away from connector pins CP1 and CP2 in a direction (dir of FIG. 5) on the daughter board D_BOARDX. On the daughter board D_BOARDY, the socket pins SPY1 and SPY2 may be located at the same positions from the connector pins CP1 and CP2 as the socket pins SPX1 and SPX2.

In some example embodiments, the distance dist may be determined based on the size of a device under test or the size of the socket SCKTX. For example, the distance dist may be increased as the size of the device under test or the size of the socket SCKTX is increased. For example, the socket SCKTX may be located on the daughter board D_BOARDX with a sufficient distance away from the connector CNCTX such that the position of the socket SCKTY on the daughter board D_BOARDY is sufficiently secured as illustrated in FIG. 6.

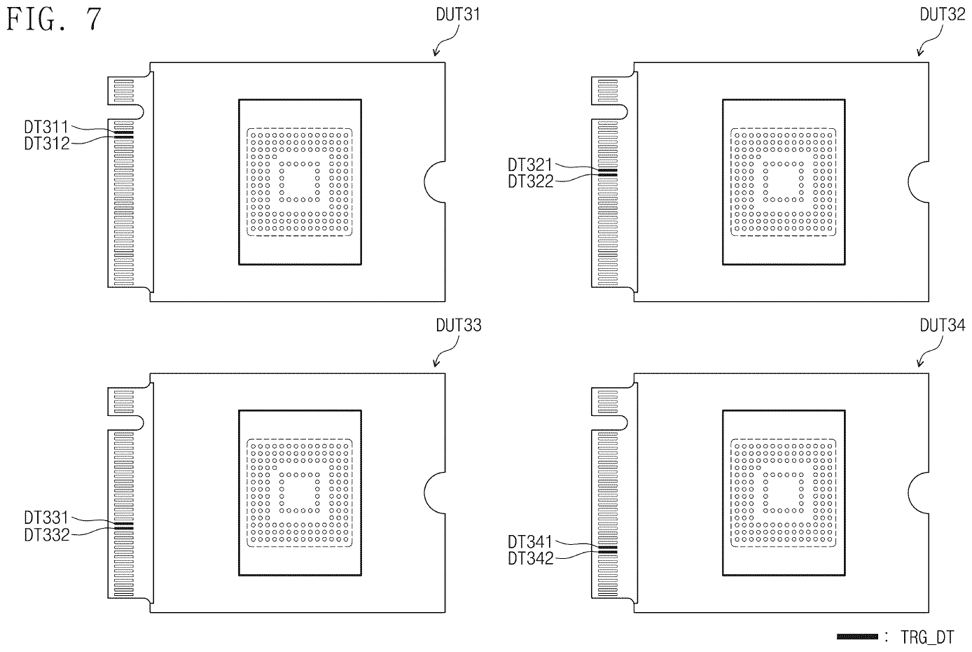

FIG. 7 is a view for explaining the output terminals of the device under test of FIG. 2B.

Devices under test DUT31, DUT32, DUT33, and DUT34 are illustrated in FIG. 7, and each of the devices under test DUT31 to DUT34 may correspond to the device under test DUTb described above with reference to FIG. 2B. Despite the illustration of FIG. 7, the devices under test DUT31 to DUT34 may be a single semiconductor device (e.g., the same semiconductor device) and may be separately illustrated for convenience to describe test signals output from different output terminals.

Referring to FIG. 7, output terminals DT311 and DT312 of the device under test DUT31, output terminals DT321 and DT322 of the device under test DUT32, output terminals DT331 and DT332 of the device under test DUT33, and output terminals DT341 and DT342 of the device under test DUT34 may be target terminals TRG_DT that output different test signals. For example, the output terminals DT311, DT312, DT321, DT322, DT331, DT332, DT341, and DT342 may be data terminals that output data signals from the devices under test DUT31 to DUT34. However, the spirit and scope of example embodiments are not limited thereto.

In some example embodiments, the devices under test DUT31 to DUT34 illustrated in FIG. 7 may be mounted on different daughter boards (or, inserted into different sockets), respectively, in the direction of coupling of the devices under test DUT31 to DUT34 in their original form, and as described above with reference to FIG. 1, the test signals output through the target terminals TRG_DT may be transmitted to an ATE (e.g., 300 of FIG. 1) under substantially the same condition.

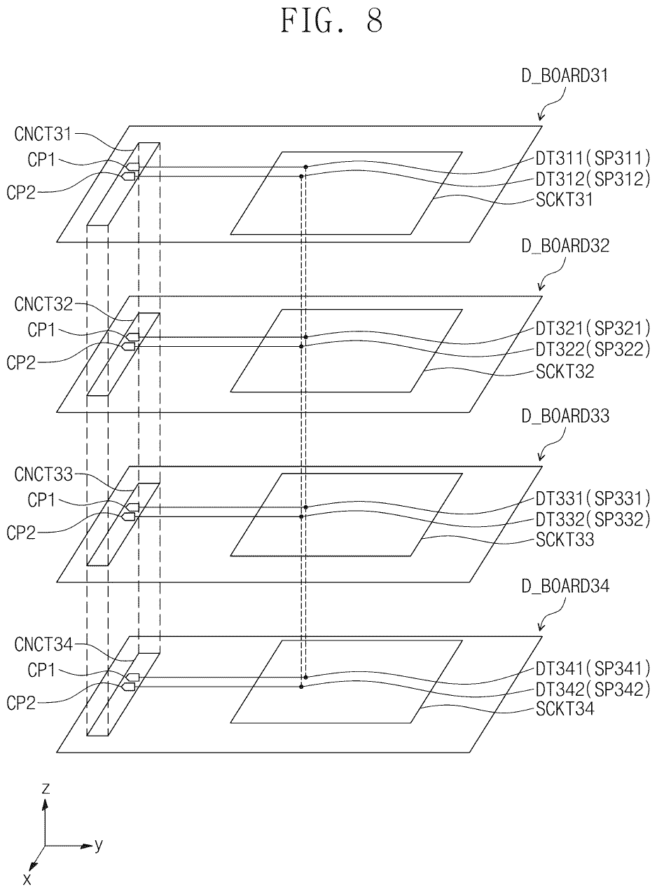

FIG. 8 is a view for explaining some example embodiments of the position of a socket to which the device under test of FIG. 2B is attached on each daughter board.

Referring to FIGS. 2B, 7, and 8, daughter boards D_BOARD31, D_BOARD32, D_BOARD33, and D_BOARD34 may have the devices under test DUT31 to DUT34 mounted thereon.

For example, the daughter board D_BOARD31 may include a socket SCKT31 for mounting the device under test DUT31 and a connector CNCT31 that is electrically connected with the socket SCKT31 and that transmits test signals output from the device under test DUT31 to a mother board. The test signals may be transmitted to the mother board through the output terminals DT311 and DT312 of the device under test DUT31, socket pins SP311 and SP312 of the socket SCKT31, and connector pins CP1 and CP2 of the connector CNCT31.

For example, the daughter board D_BOARD32 may include a socket SCKT32 for mounting the device under test DUT32 and a connector CNCT32 that is electrically connected with the socket SCKT32 and that transmits test signals output from the device under test DUT32 to the mother board. The test signals may be transmitted to the mother board through the output terminals DT321 and DT322 of the device under test DUT32, socket pins SP321 and SP322 of the socket SCKT32, and connector pins CP1 and CP2 of the connector CNCT32.

For example, the daughter board D_BOARD33 may include a socket SCKT33 for mounting the device under test DUT33 and a connector CNCT33 that is electrically connected with the socket SCKT33 and that transmits test signals output from the device under test DUT33 to the mother board. The test signals may be transmitted to the mother board through the output terminals DT331 and DT332 of the device under test DUT33, socket pins SP331 and SP332 of the socket SCKT33, and connector pins CP1 and CP2 of the connector CNCT33.

For example, the daughter board D_BOARD34 may include a socket SCKT34 for mounting the device under test DUT34 and a connector CNCT34 that is electrically connected with the socket SCKT34 and that transmits test signals output from the device under test DUT34 to the mother board. The test signals may be transmitted to the mother board through the output terminals DT341 and DT342 of the device under test DUT34, socket pins SP341 and SP342 of the socket SCKT34, and connector pins CP1 and CP2 of the connector CNCT34.

As illustrated in FIG. 8, the relative positions between the connector pins and the socket pins on the daughter boards D_BOARD31 to D_BOARD34 may be the same. For example, the relative positions between the connector pins CP1 and CP2 and the socket pins SP311 and SP312 on the daughter board D_BOARD31, the relative positions between the connector pins CP1 and CP2 and the socket pins SP321 and SP322 on the daughter board D_BOARD32, the relative positions between the connector pins CP1 and CP2 and the socket pins SP331 and SP332 on the daughter board D_BOARD33, and the relative positions between the connector pins CP1 and CP2 and the socket pins SP341 and SP342 on the daughter board D_BOARD34 may all be the same. Accordingly, an IR drop of test signals may be the same or substantially the same.

To this end, on the daughter boards D_BOARD31 to D_BOARD34, the sockets SCKT31 to SCKT34 are mounted at different positions in relation to the connectors CNT31 to CNT34. For example, the sockets SCKT31 to SCKT34 may be mounted in a parallel state or a rotated state at different positions on the daughter boards D_BOARD31 to D_BOARD34.

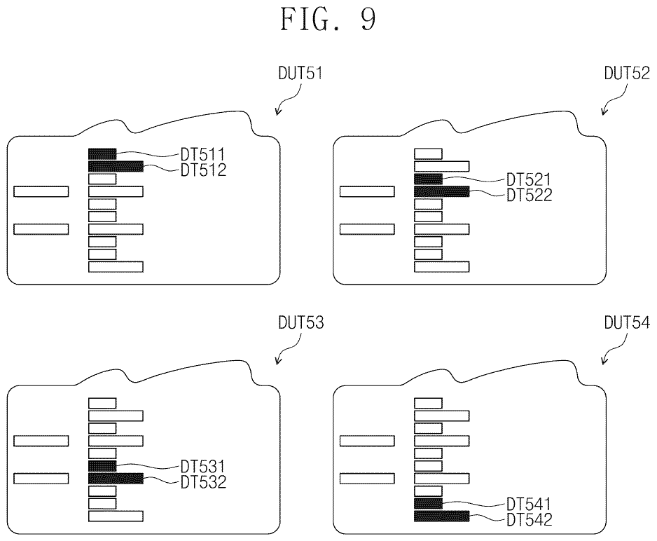

FIG. 9 is a view for explaining the output terminals of the device under test of FIG. 2C.

Devices under test DUT51, DUT52, DUT53, and DUT54 are illustrated in FIG. 9, and each of the devices under test DUT51 to DUT54 may correspond to the device under test DUTc described above with reference to FIG. 2C. Despite the illustration of FIG. 9, the devices under test DUT51 to DUT54 may be a single semiconductor device (e.g., the same semiconductor device) and may be separately illustrated for convenience to describe test signals output from different output terminals.

Referring to FIG. 9, output terminals DT511 and DT512 of the device under test DUT51, output terminals DT521 and DT522 of the device under test DUT52, output terminals DT5131 and DT532 of the device under test DUT53, and output terminals DT541 and DT542 of the device under test DUT54 may be target terminals TRG_DT that output different test signals. For example, the output terminals DT511, DT512, DT521, DT522, DT531, DT532, DT541, and DT542 may be data terminals that output data signals from the devices under test DUT51 to DUT54. However, the spirit and scope of example embodiments are not limited thereto.

In some example embodiments, the devices under test DUT51 to DUT54 illustrated in FIG. 9 may be mounted on different daughter boards (or, inserted into different sockets), respectively, in the direction of coupling of the devices under test DUT51 to DUT54 in their original form, and as described above with reference to FIG. 1, the test signals output through the target terminals TRG_DT may be transmitted to an ATE (e.g., 300 of FIG. 1) under substantially the same condition.

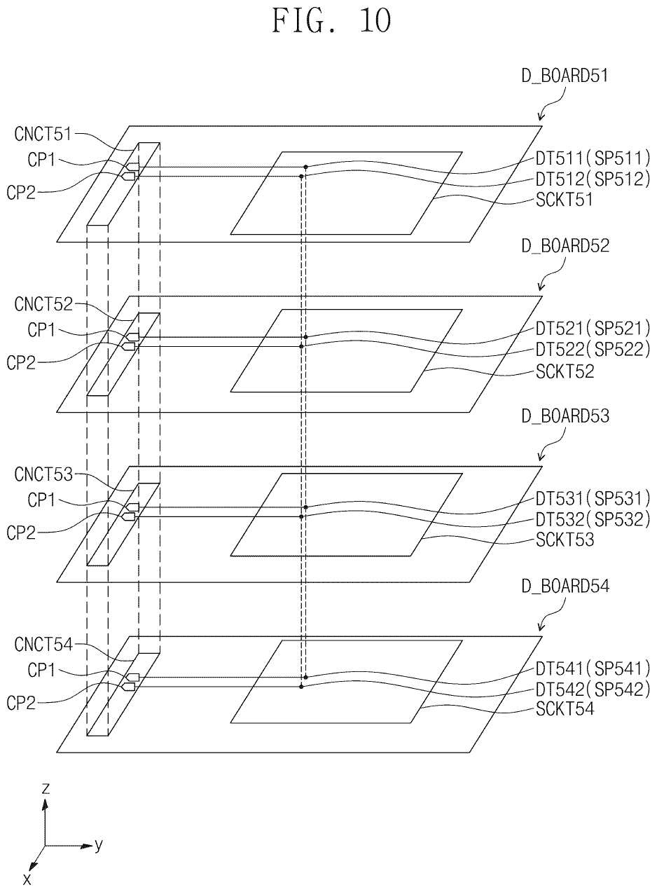

FIG. 10 is a view for explaining an embodiment of the position of a socket to which the device under test of FIG. 2C is attached on each daughter board.

Referring to FIGS. 2C, 9, and 10, daughter boards D_BOARD51, D_BOARD52, D_BOARD53, and D_BOARD54 may have the devices under test DUT51 to DUT54 mounted thereon.

For example, the daughter board D_BOARD51 may include a socket SCKT51 for mounting the device under test DUT51 and a connector CNCT51 that is electrically connected with the socket SCKT51 and that transmits test signals output from the device under test DUT51 to a mother board. The test signals may be transmitted to the mother board through the output terminals DT511 and DT512 of the device under test DUT51, socket pins SP511 and SP512 of the socket SCKT51, and connector pins CP1 and CP2 of the connector CNCT51.

For example, the daughter board D_BOARD52 may include a socket SCKT52 for mounting the device under test DUT52 and a connector CNCT52 that is electrically connected with the socket SCKT52 and that transmits test signals output from the device under test DUT52 to the mother board. The test signals may be transmitted to the mother board through the output terminals DT521 and DT522 of the device under test DUT52, socket pins SP521 and SP522 of the socket SCKT52, and connector pins CP1 and CP2 of the connector CNCT52.

For example, the daughter board D_BOARD53 may include a socket SCKT53 for mounting the device under test DUT53 and a connector CNCT53 that is electrically connected with the socket SCKT53 and that transmits test signals output from the device under test DUT53 to the mother board. The test signals may be transmitted to the mother board through the output terminals DT531 and DT532 of the device under test DUT53, socket pins SP531 and SP532 of the socket SCKT53, and connector pins CP1 and CP2 of the connector CNCT53.

For example, the daughter board D_BOARD54 may include a socket SCKT54 for mounting the device under test DUT54 and a connector CNCT54 that is electrically connected with the socket SCKT54 and that transmits test signals output from the device under test DUT54 to the mother board. The test signals may be transmitted to the mother board through the output terminals DT541 and DT542 of the device under test DUT54, socket pins SP541 and SP542 of the socket SCKT54, and connector pins CP1 and CP2 of the connector CNCT54.

As illustrated in FIG. 8, the relative positions between the connector pins and the socket pins on the daughter boards D_BOARD51 to D_BOARD54 may be the same. For example, the relative positions between the connector pins CP1 and CP2 and the socket pins SP511 and SP512 on the daughter board D_BOARD51, the relative positions between the connector pins CP1 and CP2 and the socket pins SP521 and SP522 on the daughter board D_BOARD52, the relative positions between the connector pins CP1 and CP2 and the socket pins SP531 and SP532 on the daughter board D_BOARD53, and the relative positions between the connector pins CP1 and CP2 and the socket pins SP541 and SP542 on the daughter board D_BOARD54 may all be the same. Accordingly, the IR drop of test signals may be the same or substantially the same.

To this end, on the daughter boards D_BOARD51 to D_BOARD54, the sockets SCKT51 to SCKT54 are mounted at different positions in relation to the connectors CNT51 to CNT54. For example, the sockets SCKT51 to SCKT54 may be mounted in a parallel state or a rotated state at different positions on the daughter boards D_BOARD51 to D_BOARD54.

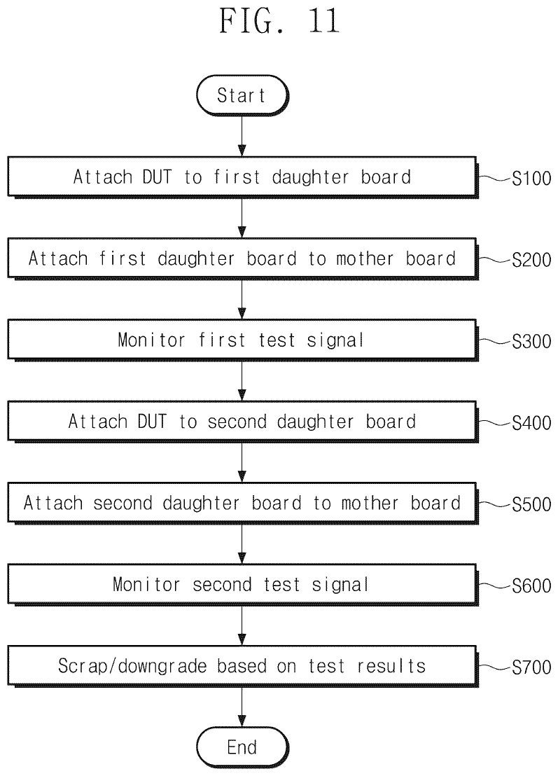

FIG. 11 is a flowchart illustrating a test method according to some example embodiments.

Referring to FIG. 11, a device under test may be attached to a first daughter board such that a first output terminal of the device under test is located at a first point of the first daughter board (S100).

In some example embodiments, the first point may correspond to a socket pin of a socket mounted on the first daughter board (e.g., D_BOARD11 of FIG. 4) and may be a point at which a socket pin (e.g., SP111) electrically connected with the first output terminal DT111 is located.

The first daughter board may be attached to a mother board such that a connector of the first daughter board is located at a reference point of the mother board (S200).

In some example embodiments, the reference point of the mother board may be a point at which the mother board and the first daughter board are coupled. For example, the reference point of the mother board may be a point at which a connector of the mother board is located.

A first test signal output from the first output terminal may be monitored (S300).

The device under test may be attached to a second daughter board such that a second output terminal of the device under test is located at a second point of the second daughter board (S400).

In some example embodiments, the second point may correspond to a socket pin of a socket mounted on the second daughter board (e.g., D_BOARD12 of FIG. 4) and may be a point at which a socket pin (e.g., SP121) electrically connected with the second output terminal DT121 is located.

The second daughter board may be attached to the mother board such that a connector of the second daughter board is located at the reference point of the mother board (S500).

In some example embodiments, the reference point of the mother board may be a point at which the mother board and the second daughter board are coupled. For example, the reference point of the mother board may be a point at which the first daughter board is coupled with the mother board and then replaced. For example, the reference point of the mother board may be or may correspond to a point at which the connector of the mother board is located.

A second test signal output from the second output terminal may be monitored (S600).

In some example embodiments, the device under test may be scrapped or downgraded based on the first test signal and/or the second test signal (S700). Alternatively or additionally in some example embodiments, a manufacturing process for semiconductor manufacturing may be modified based on the first and/or second test signal.

In some example embodiments, the direction and distance from the point at which the connector of the first daughter board is located to the first point may be the same as the direction and distance from the point at which the connector of the second daughter board is located to the second point. For example, the first point and the second point may be determined in a manner similar to the manner described above with reference to FIGS. 5 and 6.

As described above, the test device according to the some example embodiments may transmit the different test signals from the device under test to the ATE under the same condition to improve the signal integrity of the test signals, thereby preventing the test result of the semiconductor device from being adversely affected by the structure and characteristics of the test board itself and/or improving the reliability of analysis. In the test device, the daughter boards may be manufactured separately from the mother board so as to be detachable, and only the daughter boards may be newly manufactured for a new device under test. Accordingly, it is possible to reduce the manufacturing time and/or cost of the test board while supporting various form factors.

The test device according to the some example embodiments may transmit the different test signals from the device under test to the automatic test equipment (ATE) under the same condition to improve the signal integrity of the test signals, thereby preventing the test result of the semiconductor device from being adversely affected by the structure and characteristics of the test board itself and improving the reliability of analysis. In the test device, the daughter boards may be manufactured separately from the mother board so as to be detachable, and only the daughter boards may be newly manufactured for a new device under test. Accordingly, it may be possible to reduce the manufacturing time and/or cost of the test board while supporting various form factors.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While some example embodiments have been described with reference to embodiments thereof, it will be apparent to those of ordinary skill in the art that various changes and modifications may be made thereto without departing from the spirit and scope of the present disclosure as set forth in the following claims. Additionally or alternatively, example embodiments are not necessarily mutually exclusive with one another. For example, some example embodiments may include one or more features described with reference to one or more figures, and may also include one or more other features described with reference to one or more other figures.

What is claimed is:

1. A test device comprising:
a mother board; and
a plurality of daughter boards selectively coupled to the mother board and configured to provide a plurality of test signals from a device under test to the mother board,
wherein each of the plurality of daughter boards includes,
a substrate,
a socket mounted on the substrate and configured to output a corresponding test signal among the plurality of test signals through a first socket pin, and
a connector mounted on the substrate and configured to output the corresponding test signal from the socket to the mother board through a first connector pin, and
wherein relative positions between the first connector pins and the first socket pins on the plurality of daughter boards are same.

2. The test device of claim 1, wherein at least one of directions and distances from the first connector pins to the first socket pins on the plurality of daughter boards are same.

3. The test device of claim 1, wherein a position of the socket on the substrate is determined such that the first socket pin is located at a particular point on the substrate.

4. The test device of claim 3, wherein the first socket pin is located a first distance away from the first connector pin in a first direction.

5. The test device of claim 4, wherein the first direction is perpendicular to a lengthwise direction of the connector.

6. The test device of claim 4, wherein the first distance is determined based on at least one of a size of the device under test or a size of the socket.

7. The test device of claim 1, wherein
the socket includes the first socket pin and includes a plurality of socket pins arranged in a line, and
the connector includes the first connector pin and includes a plurality of connector pins arranged in a line.

8. The test device of claim 7, wherein the plurality of socket pins and the plurality of connector pins are parallel to each other.

9. The test device of claim 7, wherein
the plurality of socket pins further include a second socket pin adjacent to the first socket pin, and
the plurality of connector pins further include a second connector pin adjacent to the first connector pin.

10. The test device of claim 9, wherein
the first socket pin is located a first distance away from the first connector pin in a first direction, and
the second socket pin is located the first distance away from the second connector pin in the first direction.

11. The test device of claim 10, wherein the first direction is perpendicular to a lengthwise direction of the connector.

12. The test device of claim 1, wherein each of the plurality of daughter boards are configured to couple to the device under test.

13. The test device of claim 1, wherein the socket on one of the plurality of daughter boards is located at a point moved in parallel or rotated when compared to the socket on another one of the plurality of daughter boards.

14. The test device of claim 1, wherein the mother board includes a power supply circuit configured to supply power to a daughter board coupled to the mother board.

15. A test board comprising:
a substrate;
a socket mounted on the substrate and configured to output a first test signal through a first socket pin, the first test signal among a plurality of test signals from a device under test; and
a connector mounted on the substrate and configured to output the first test signal from the socket to a mother board through a first connector pin,
wherein the test board is one of a plurality of daughter boards selectively coupled to the mother board and configured to provide the plurality of test signals to the mother board, and
a position of the socket is determined such that the first socket pin is located a first distance away from the first connector pin in a first direction.

16. The test board of claim 15, wherein the first direction is perpendicular to a lengthwise direction of the connector.

17. The test board of claim 16, wherein the first distance is determined based on a size of the device under test or a size of the socket.

18. The test board of claim 15, wherein
the socket includes the first socket pin and includes a plurality of socket pins arranged in a line,
the connector includes the first connector pin and includes a plurality of connector pins arranged in a line, and
the plurality of socket pins and the plurality of connector pins are parallel to each other.

19. The test board of claim 15, wherein the test board is configured to test a device under test having at least one of universal flash storage (UFS) fine pitch ball grid array (FBGA) type, an M.2 type, or a card type.

20. A test method comprising:
attaching a device under test to a first daughter board such that a first output terminal of the device under test is located at a first point of the first daughter board;
attaching the first daughter board to a mother board such that a connector of the first daughter board is located at a reference point of the mother board;
testing a first test signal output from the first output terminal;
attaching the device under test to a second daughter board such that a second output terminal of the device under test is located at a second point of the second daughter board;
attaching the second daughter board to the mother board such that a connector of the second daughter board is located at the reference point of the mother board; and
testing a second test signal output from the second output terminal,
wherein at least one of a direction and a distance from a point at which the connector of the first daughter board is located to the first point are same as a respective one of a direction and a distance from a point at which the connector of the second daughter board is located to the second point.
